(19) United States
(12) Patent Application Publication
(10) Pub. No.: US 2017/0155161 A1
(43) Pub. Date: Jun. 1, 2017

(54) ELECTRICAL CONNECTOR AND ELECTROCHEMICAL REACTOR EQUIPPED WITH SUCH AN ELECTRICAL CONNECTOR

(71) Applicant: Commissariat A L'Energie Atomique et aux Energies Alternatives, Paris (FR)

(72) Inventors: Jean-Philippe POIROT-CROUVEZIER, Saint Georges de Commiers (FR); Laurent GARNIER, Marennes (FR); Jean ORIOL, Le Plessis-Trevise (FR); Mickael ROBERT, Goncelin (FR)

(73) Assignee: Commissariat A L'Energie Atomique et aux Energies Alternatives, Paris (FR)

(21) Appl. No.: 15/361,275

(22) Filed: Nov. 25, 2016

(30) Foreign Application Priority Data
Nov. 27, 2015 (FR) 15 61515

(51) Int. Cl. H01M 8/04537; G01R 19/14; H01M 8/2404

(52) U.S. Cl. CPC H01M 8/04656; H01M 8/2404; G01R 19/14; H01M 2008/1095

(57) ABSTRACT

An electrochemical reactor is provided, including an electrical connector including an end part occupying a position referred to as engaged in a stack of electrochemical cells, including: an electrical contact portion; and a blocking portion, including: either a blocking through-orifice receiving by insertion an abutment element of an electrochemical cell, or a blocking element introduced by insertion into an abutting through-orifice of the electrochemical cell, the insertion, when the end part occupies the engaged position, leading to the formation of an abutment opposing the retraction of the end part out of the engaged position.

### TECHNICAL FIELD

The field of the invention is that of electrochemical reactors, such as fuel cells and electrolyzers, comprising a stack of electrochemical cells, and relates more particularly to the electrical connection of at least one of the electrochemical cells notably with a view to measuring a value of the electrical polarization of the electrochemical cell. The invention is for example applicable to the evaluation and to the monitoring of the state of health of an electrochemical cell.

### PRIOR ART

An electrochemical reactor, such as a fuel cell or an electrolyzer, usually comprises a stack of electrochemical cells each of which comprises an anode and a cathode electrically separated from each another by an electrolyte, the cells being the seat of an electrochemical reaction between two reagents being continuously introduced.

In the case of a fuel cell, the fuel (for example hydrogen) is carried to the anode whereas the oxidizer (for example oxygen) is brought to the cathode. The electrochemical reaction is subdivided into two half-reactions, an oxidation reaction and a reduction reaction, which take place respectively at the anode/electrolyte interface and at the cathode/electrolyte interface. In order to take place, the electrochemical reaction requires the presence of an ionic conductor between the two electrodes, namely the electrolyte for example contained within a polymer membrane, and an electronic conductor formed by the external electrical circuit. The stack of cells is thus the seat of the electrochemical reaction: the reagents must be taken thereto, the products and the non-reactive species must be evacuated therefrom, as must the heat produced during the reaction.

The electrochemical cells are usually separated from one another by bipolar plates which provide the electrical interconnection of the cells. The plates usually comprise an anode face on which a distribution circuit for the fuel is formed, and a cathode face, opposite to the anode face, on which a distribution circuit for the oxidizer is formed. Each distribution circuit takes the form of a network of channels arranged for example in parallel or as a serpentine in order to bring the reactive species in a uniform manner to the corresponding electrode. The bipolar plates may also comprise a cooling circuit composed of a network of internal conduits which provides the flow channel for a cooling fluid allowing the heat produced locally during the reaction by the cell to be evacuated.

The evaluation of the state of health of the electrochemical reactor may require an electrical characteristic associated with one or another of the electrochemical cells to be measured, such as the voltage or the impedance of an electrochemical cell. A measurement of the electrical polarization of a bipolar plate of the cell in question is then carried out.

The document U.S.20030072983 describes one example of an electrical connector inserted into a stack of electrochemical cells. The cells comprise bipolar plates whose lateral edge has a structural arrangement in the form of a groove. The electrical connector comprises a plurality of parts, referred to as end parts, designed to be inserted into the grooves of the bipolar plates, which are extended by parts referred to as external parts connecting the end parts to an electronic board for measuring the electrical polarization. The end parts come into contact with the bipolar plates within the grooves and a measurement of the electrical polarization may be carried out.

The document JP2007220338 describes another example of an electrical connector inserted into a stack of electrochemical cells. The bipolar plates of the cells also comprise a groove situated on a lateral edge together with a fixing embossment making a protrusion into the groove. The end parts of the electrical connector each comprise a notch designed to come into contact with the fixing embossment when the end parts are engaged in the grooves of the bipolar plates.

There however exists a need to improve the reliability of the electrical measurement via the electrical connector, the latter depending notably on the quality of the mechanical contact between the electrical connector and the bipolar plate. There also exists a need for an electrical connector which is compatible with electrochemical cells of limited thickness.

### DESCRIPTION OF THE INVENTION

The aim of the invention is to overcome, at least in part, the drawbacks of the prior art and, more particularly, to provide an electrical connector that offers an improved mechanical strength when it occupies a position referred to as engaged in the stack of electrochemical cells, thus improving the reliability of the electrical measurement via the electrical connector. For this purpose, the subject of the invention is an electrical connector designed to provide an electrical connection with one electrochemical cell of a stack of electrochemical cells, each electrochemical cell comprising two electrodes separated from one another by an electrolyte, the said electrodes being in electrical contact with bipolar plates, the electrical connector comprising an end part designed to be inserted into the stack of electrochemical cells so as to occupy a position referred to as engaged.

The said end part comprises an electrical contact portion, designed to be in electrical contact with a bipolar plate of the said electrochemical cell when the end part occupies the engaged position; and a blocking portion, designed to cooperate with the said electrochemical cell in order to ensure the maintenance of the end part in the engaged position.

The blocking portion comprises either a blocking through-orifice designed to receive by insertion an abutment element of the electrochemical cell, or a blocking element designed to be introduced by insertion into an abutting through-orifice of the electrochemical cell; the said insertion, when the end part occupies the engaged position, leading to the formation of an abutment opposing the retraction of the end part out of the engaged position.

According to the invention, the end part is composed of an electrical cable comprising a conducting core in the form of a strip having two faces opposing each other coated with an insulating sheath, and may have an average thickness, between two main faces of the end part substantially parallel and opposite to each other, less than the width and length dimensions of the said main faces.

Some preferred but non-limiting aspects of this electrical connector are the following:

The said blocking through-orifice or the said blocking element may extend in a thickness direction of the end part and is electrically isolated from the conducting core.

The electrical contact portion and the blocking portion may be distinct from each other and be mutually spaced out in a longitudinal axis of the electrical connector.

The blocking portion may comprise a blocking through-orifice adapted to receive an abutment element chosen from amongst a centring pin passing through the stack of electrochemical cells, a removable insert, or an embossment formed by the said bipolar plate.

The blocking portion may comprise an open slot extending from the said blocking through-orifice up to a lateral edge of the blocking portion, the said open slot having a width substantially less than the diameter of the blocking through-orifice.

The said blocking through-orifice of the blocking portion may extend up to a lateral edge of the blocking portion at an opening area of the said blocking orifice, the latter being positioned between the blocking through-orifice and the electrical contact portion.

The blocking portion may comprise a blocking element in the form of an embossment designed to be inserted into an abutting through-orifice of the electrochemical cell.

The electrical contact portion may comprise a main face, designed to be oriented towards the said bipolar plate, having an area without any insulating sheath freeing up a contact surface of the conducting core, the said contact surface being designed to be in electrical contact with the said bipolar plate.

The said contact surface of the conducting core may have at least one structural arrangement making a protrusion with respect to a main plane in which the contact surface of the conducting core substantially extends, the said protruding structural arrangement being preferably elastically deformable.

The electrical connector may comprise a plurality of separate end parts designed to provide an electrical connection with several bipolar plates, the said end parts being mechanically connected to the same part referred to as external part of the electrical connector.

The invention also relates to an electrochemical reactor, comprising:

a stack of electrochemical cells each comprising two electrodes separated from each other by an electrolyte and in electrical contact with bipolar plates, and comprising at least one abutment element or one abutting through-orifice of an electrochemical cell;
at least one electrical connector according to any one of the preceding claims, providing an electrical connection with the said electrochemical cell, whose end part is inserted into the stack of electrochemical cells and occupies the position referred to as engaged, in such a manner that the blocking through-orifice receives by insertion the said abutment element or such that the blocking element is introduced by insertion into the said abutting through-orifice, the said insertion leading to the formation of an abutment opposing the retraction of the end part out of the engaged position.

The said bipolar plates may comprise contact embossments, preferably elastically deformable, the end part comprising a contact portion in contact with the said contact embossments.

The invention also relates to a method for fabricating an electrochemical reactor according to one or the other of the preceding features, comprising a step for formation of the stack of electrochemical cells, during which, between two stacks of bipolar plates, the electrical connector is stacked in such a manner that the end part occupies the engaged position, resulting in:

an electrical contact between the electrical contact portion and a bipolar plate, and
the formation of an abutment opposing the retraction of the end part out of the engaged position by the insertion of the said abutment element into the blocking through-orifice or by the insertion of the said blocking element into the said abutting through-orifice.

### BRIEF DESCRIPTION OF THE DRAWINGS

Other aspects, aims, advantages and features of the invention will become more clearly apparent upon reading the following detailed description of preferred embodiments of the latter, given by way of non-limiting example, and presented with reference to the appended drawings in which:

FIG. 1a is an exploded perspective illustration of a part of an electrochemical reactor according to one embodiment, where an electrical connector is inserted into the stack of electrochemical cells; FIG. 1b is a non-exploded illustration of the same part of the electrochemical reactor in FIG. 1a;

FIGS. 2a and 2b are perspective views of the electrical connector illustrated in FIGS. 1a and 1b, where the blocking portion is not deformed (FIG. 2a) and deformed (FIG. 2b);

FIG. 3 is a perspective view of the electrical connector according to one variant of the embodiment illustrated in FIGS. 2a and 2b;

FIGS. 4a to 4f are schematic views in longitudinal cross-section of the blocking of the electrical connector to the electrochemical cell according to several variant embodiments, in which the blocking portion comprises:

a through-orifice, referred to as blocking orifice, into which a separate thrust-bearing insert rigidly fixed to the electrochemical cell is inserted (FIGS. 4a and 4b);
a through-orifice referred to as blocking orifice into which an abutting embossment of a bipolar plate of the electrochemical cell is inserted (FIGS. 4c and 4d);
an element referred to as blocking element inserted into an abutting through-orifice of a bipolar plate of the electrochemical cell (FIGS. 4e and 4f);

FIGS. 5a and 5b are perspective views of two variants of the electrical connector in which the electrical contact portion comprises structural arrangements of the conducting core making a protrusion with respect to a main plane of the end part of the electrical connector;

FIG. 6 is a schematic longitudinal cross-section view of an area of contact of the electrical connector to the electrochemical cell according to another embodiment, in which the bipolar plates comprise elastically deformable contact embossments;

FIGS. 7a and 7b are perspective views of an electrical connector according to another embodiment in which several end parts are mechanically connected to the same part referred to as external part of the electrical connector.

### DETAILED DESCRIPTION OF PARTICULAR EMBODIMENTS

In the figures and in the following part of the description, the same references represent identical or similar elements. Moreover, the various elements are not shown to scale for the sake of clarity of the figures.

Various embodiments and their variants will be described with reference to a fuel cell, and in particular to a hydrogen fuel cell whose cathode is supplied with oxygen and anode with hydrogen. The invention is applicable, generally speaking, to any type of fuel cell, in particular to those operating at low temperature, in other words at a temperature lower than 250° C., and also to electrochemical electrolyzers and, generally speaking, to any type of electrochemical reactor comprising a stack of electrochemical cells.

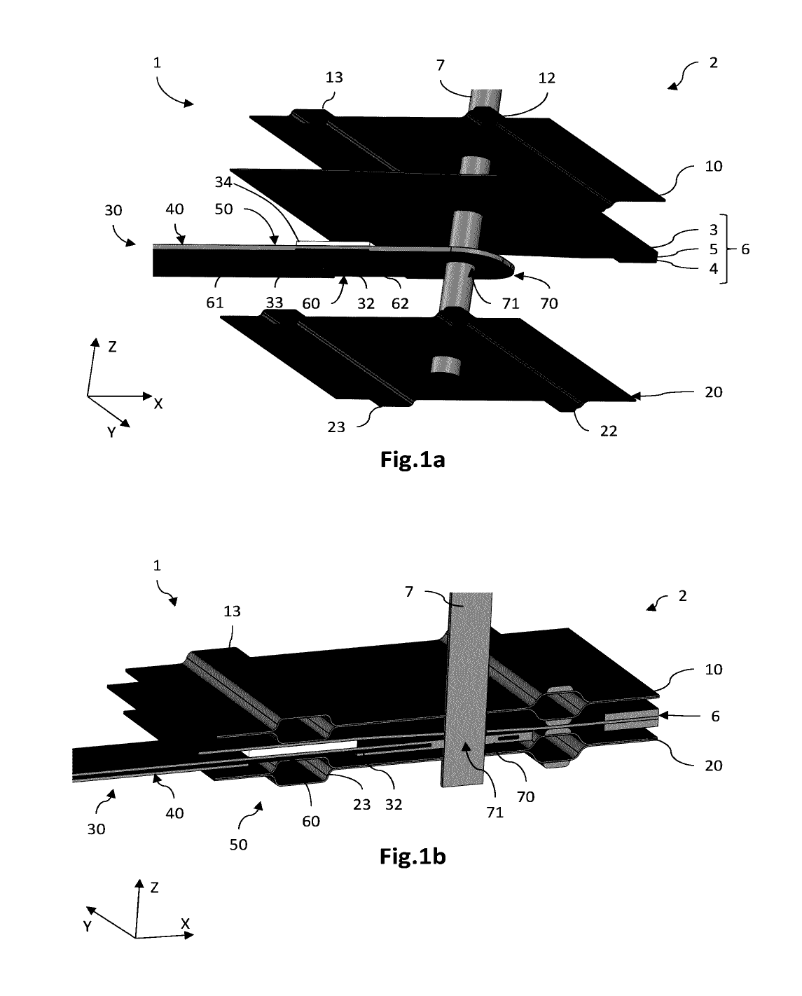

FIG. 1a is an exploded view of a part of a fuel cell 1 according to one embodiment, the fuel cell comprising a stack of electrochemical cells 2 into which an electrical connector 30 is inserted.

A three-dimensional orthonormal reference frame (X,Y,Z) is defined here and for the following part of the description, where the X and Y axes are oriented in a main plane according to which the electrochemical cells extend, and the Z axis is oriented in a manner substantially orthogonal to the main plane of the cells.

The electrochemical cells 2 are preferably identical to one another. They each comprise an anode 3 and a cathode 4 separated from each other by an electrolyte 5 here contained in a electrically-insulating polymer membrane. The entire assembly of the electrodes and of the electrolytic membrane is henceforth referred to as EMA 6 for Electrode-Membrane Assembly. The anode, the membrane and the cathode are conventional elements known to those skilled in the art and are not described in detail. The EMA 6 is oriented in a main cell plane here substantially parallel to the plane (X,Y).

Each EMA 6 is disposed between separators 10, 20 referred to in the following as bipolar plates. The bipolar plates 10, 20 each comprise a first main face, referred to as anode face, designed to be partially in contact with an anode 3 and a second main face opposite to the anode face, referred to as cathode face, designed to be partially in contact with a cathode 4. Each bipolar plate ensures the transmission of the electrical current between the electrochemical cells and thus has a value of electrical polarization which it may be desirable to measure.

The bipolar plates 10, 20 here are each composed of two parts assembled together, for example two electrically-conducting metal plates whose embossments, formed notably by a stamping die, form conduits for distribution of the reactive species and cooling conduits. As a variant, the two assembled parts may be made of a composite material charged for example with graphite, where the embossments are obtained by moulding.

In FIG. 1a, a part of one electrochemical cell 2 of the stack of cells is shown, for which here it is desired to measure a value of electrical polarization. The bipolar plates 10, 20 have a surface area greater than that of the EMA such that they have a lateral edge that surrounds the EMA 6.

In this example, the membrane 5 has a surface area substantially equal to that of the bipolar plates 10, 20 and also extends as far as the lateral edge of the latter. It provides the electrical isolation between the two bipolar plates. Alternatively, the membrane 5 may furthermore comprise an additional sheet forming a local peripheral reinforcement, or even be formed from a single sheet forming a local reinforcement, distinct from the electrolytic membrane of the EMA 6.

In order to ensure that the stack of electrochemical cells is mechanically robust, the bipolar plates here comprise first embossments 12, 22 surrounding the EMA 6 and arranged in such a manner as to be in mutual contact by means of the membrane and of peripheral seals. The bipolar plates here comprise second embossments 13, 23, referred to as contact embossments, situated on the lateral edge of the electrochemical cell and surrounding the first embossments 12, 22. The contact embossments 13, 23 here are in mutual contact by means of the membrane 5, and locally, by means of an electrical connector 30.

In addition, in such a manner as to ensure that the stack of electrochemical cells is mechanically robust and, in particular, in order to ensure the mutual positioning of the electrochemical cells within the plane (X,Y), an insert 7 is introduced into a through-opening of the bipolar plates 10, 20 and extends along the Z axis of the stack of electrochemical cells. This insert 7 is a rigid rod, henceforth referred to as centring pin or tie rod, and may participate in applying a compression force on the stack of electrochemical cells. The centring pin 7 here is situated between the first embossments 12, 22 and the contact embossments 13, 23.

With the aim of providing an electrical connection between the electrochemical cell and an electronic board for measurement or for application of an electrical potential, an electrical connector 30 is inserted into the stack of cells at the electrochemical cell 2, here between the two bipolar plates 10, 20 of the latter.

The electrical connector 30 comprises a part referred to as external part 40 and a part referred to as end part 50. The end part 50 is inserted into the stack of cells and is connected to an electronic board (not shown) by means of the external part 40, the electronic board being designed to measure or to apply an electrical potential to the electrochemical cell.

The electrical connector 30, and in particular the end part 50, take the form of a substantially flat electrical cable, in the sense that it has an average thickness less than its width and length dimensions. It comprises two main faces substantially parallel and opposite to each other, whose relative distance define the average thickness of the electrical connector. Furthermore, it comprises a conducting core 32 in the form of a substantially flat strip whose two faces are coated with an insulating sheath 33. ‘Electrical cable’ is understood to mean an assembly composed of a conducting core covered by an insulating sheath. ‘Covered’, or ‘coated’, is understood to mean that the two main faces of the conducting core are covered by the insulating sheath over their whole surface, with the exception of at least one area designed to provide the electrical contact between the conducting core and a bipolar plate.

The electrical cable may be a flexible flat cable formed by lamination. The conducting core 32 may be formed from a metal foil, for example of copper or of aluminium with an average thickness of the order of 10 μm to 500 μm. The insulating sheath 33 is made from an electrically-insulating material, for example polyimide with an average thickness of the order of 10 μm to 500 μm. The electrical cable may have an average thickness in the range between 20 μm and 1 mm, and preferably in the range between 20 μm and 500 μm, for example in the range between 100 μm and 200 μm. It may have a width in the range between 5 mm and 5 cm, for example equal to 1 cm.

The end part 50 of the electrical connector comprises an electrical contact portion 60 and a blocking portion 70, that are separate and spaced out from each other along the longitudinal axis of the electrical connector.

When the end part 50 is inserted into the stack of electrochemical cells and occupies a position referred to as engaged, the electrical contact portion 60 is in electrical contact with a bipolar plate 20 of the electrochemical cell. In this example, the electrical contact portion 60 comprises a main face 61 oriented towards the bipolar plate 20 to be contacted, one area of which is lacking the insulating sheath 33, thus freeing up a contact surface 62 of the conducting core 32. The contact surface 62 here is in direct contact with the contact embossment 23 of the bipolar plate 20. Thus, an electrical contact is provided between the conducting core 32 and the bipolar plate 20. More precisely, the insulating sheath 30 coats the conducting core 32 over the two main faces of the latter, and runs over the entire longitudinal extent of the end part 50, except for here in the area of the contact surface 62. It thus covers the main face 61, together with the opposing main face, over the whole length of the end part 50. The insulating sheath 30 is preferably fixed to the conducting core 32 in a non-removable manner.

In addition, when the end part 50 is inserted into the stack of electrochemical cells and occupies a position referred to as engaged, the blocking portion 70 cooperates with the electrochemical cell in order to ensure that the end part 50 is held in the engaged position. In this example, the blocking portion 70 comprises a through-orifice referred to as blocking orifice 71, extending in the direction of the thickness of the electrical connector, into which an abutment element 7 of the electrochemical cell is inserted. The abutment element here is the centring pin 7, the latter being rigidly attached to the electrochemical cell. Thus, the insertion of the centring pin 7 into the blocking through-orifice 71 of the electrical connector leads to the formation of an abutment opposing the retraction of the end part 50 out of the engaged position and hence out of the stack of electrochemical cells.

The blocking through-orifice 71 has a shape advantageously complementary to that of the centring pin 7. Here, it is substantially circular but other shapes are possible, for example oval, oblong, or even polygonal. The diameter of the blocking orifice here is a physical quantity associated with the perimeter of the orifice. This may be the diameter of a disc having the same surface area as that of the through-orifice

The blocking through-orifice 71 is preferably electrically isolated from the conducting core 32. For this purpose, here it is defined by a portion of insulating sheath 33 over the whole thickness of the blocking portion 70, thus avoiding any electrical contact between the conducting core 32 and the centring pin 7, this electrical contact being able to interfere with the electrical connection between the conducting core and the bipolar plate.

Furthermore, the electrical connector 30 here comprises a compression layer 34 situated on the electrical contact portion 60 and positioned on the main face opposite to the contact surface 62. Thus, the compression layer 34 is interposed between the insulating sheath 33 and the contact embossment 13 of the bipolar plate 10, and is advantageously made of an electrically-insulating material. It thus ensures a better mechanical, and hence electrical, contact between the conducting core 32 and the bipolar plate 20. The compression layer 34 may be made of an elastic material so as to be able to adapt to the thickness tolerances and to the thermal expansions of the bipolar plates and of the electrical connector. It may thus be made of an elastomer and/or of an expanded foam.

FIG. 1b is a perspective view of the fuel cell part illustrated in FIG. 1a, in which the various elements are in mutual contact.

The end part 50 is in the engaged position, in such a manner that the electrical contact portion 60 is such that the conducting core 32 is in electrical contact with the bipolar plate 20 on the contact embossment 23, and in such a manner that the blocking portion 70 is such that the blocking through-orifice 71 receives by insertion the centring pin 7.

Thus, the end part 50 of the electrical connector is blocked from movement in the directions X, Y, Z, and cannot be disengaged and removed from the stack of electrochemical cells. Indeed, the end part 50 is blocked from movement along the Z axis of the stack of cells by the mechanical contact with the contact embossments 13, 23 of the bipolar plates. In addition, it is blocked in translation in the plane (X,Y) by the abutment formed between the centring pin 7 and the blocking through-orifice 71 of the blocking portion.

When it occupies the engaged position, the electrical connector 30 thus exhibits an improved mechanical stability which leads to a higher quality of the electrical connection and hence a greater reliability of the measurements or applications of the electrical potential. Indeed, when the end part occupies the engaged position, impacts and vibrations to which the fuel cell may be subjected in operation cannot cause the removal of the electrical connector out of the stack of cells.

Moreover, since the electrical connector takes the form of a substantially flat electrical cable, it can be inserted between the bipolar plates without causing a significant increase in thickness for the stack of cells. It may also be introduced between the bipolar plates in an area where the latter are usually in mechanical contact, for example between the contact embossments.

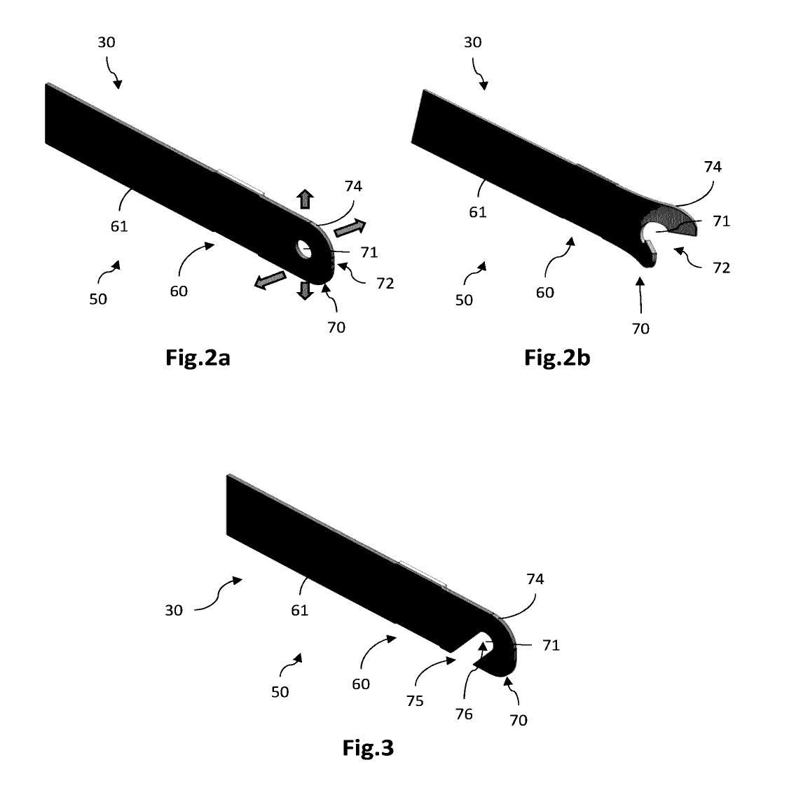

FIGS. 2a and 2b are perspective views of the electrical connector such as illustrated in FIGS. 1a and 1b, which show one example of a structural arrangement allowing the centring pin to be inserted into the blocking through-orifice of the end part.

In this example, the blocking portion 70 comprises a open slot 72 which extends from the blocking orifice 71 up to a lateral edge 74 of the blocking portion 70, here situated in the longitudinal extension of the blocking through-orifice 71. The slot 72 has a width substantially less than the diameter of the blocking through-orifice 71, the width being defined as the gap between the two branches of the blocking portion 70 facing each other in the slot 72.

The blocking portion 70 here is elastically deformable, such that the application of separation forces on the slot 72, oriented for example according to the arrows shown in FIG. 2a, leads to the opening of the blocking portion (FIG. 2b), thus allowing the centring pin 7 to be inserted into the blocking through-orifice 71.

Once the centring pin 7 has been inserted into the blocking through-orifice 71, the blocking portion 70 returns to its initial shape in such a manner that the centring pin 7 is continuously surrounded by the blocking portion 70. An abutment is then formed between the centring pin 7 and the electrical connector 30, which then opposes the retraction of the end part 50 out of the engaged position.

A method for implementation of the fuel cell such as partially illustrated in FIG. 1b is now described.

The various elements of the electrochemical cells are successively stacked on top of one another along the centring pin 7. Thus, the bipolar plate 20 is stacked onto a preceding electrochemical cell and is traversed by the centring pin 7.

Subsequently, the electrical connector 30 is stacked such that the end part 50 occupies the engaged position. The electrical contact portion 60 is then in electrical contact with the contact embossment 23 of the bipolar plate 20 and the blocking through-orifice 71 receives by insertion the centring pin 7.

Then, the EMA 6 then the bipolar plate 10 are stacked onto the bipolar plate 20 and the end part 50 of the electrical connector. The membrane 5 is then in mechanical contact with the electrical contact portion 60 on the compression layer 34. The contact embossment 13 of the bipolar plate 10 is aligned in the plane (X,Y) with that 23 of the bipolar plate 20.

Lastly, the various elements of the following electrochemical cells are stacked so as to obtain a stack of electrochemical cells into which the electrical connector is inserted.

Thus, the electrical connector 30 is blocked in translation in the plane (X,Y) by the abutment formed by the insertion of the centring pin 7 into the blocking through-orifice 71, and in the direction Z by the mechanical contact with the bipolar plates 10, 20 on the contact embossments 13, 23. The electrical connection is then robust against vibrations and impacts that the fuel cell is likely to undergo during its operation, without the latter affecting the mechanical stability of the electrical connector in its engaged position or degrading the quality of the electrical connection with the electrochemical cell.

FIG. 3 shows one variant embodiment of the electrical connector 30 such as previously illustrated, which differs from it essentially in that the blocking through-orifice 71 extends between a main blocking area 76 situated substantially in the centre of the blocking portion 70 and an open-ended area 75 situated on the lateral edge 74 of the blocking portion 70. The blocking through-orifice 71 here has a width that is substantially constant, and advantageously equal to or greater than the transverse diameter of the centring pin 7.

Furthermore, the open-ended area 75 is advantageously situated upstream of the main area 76 in the direction of the external part 40 of the electrical connector. Thus, when the centring pin 7 is inserted into the blocking orifice 71, a retraction force leads the centring pin 7 to occupy the main area 76 and to abut against an internal border of the blocking orifice 71. Thus, an abutment is formed between the electrical connector and the centring pin which opposes the retraction of the end part out of the engaged position.

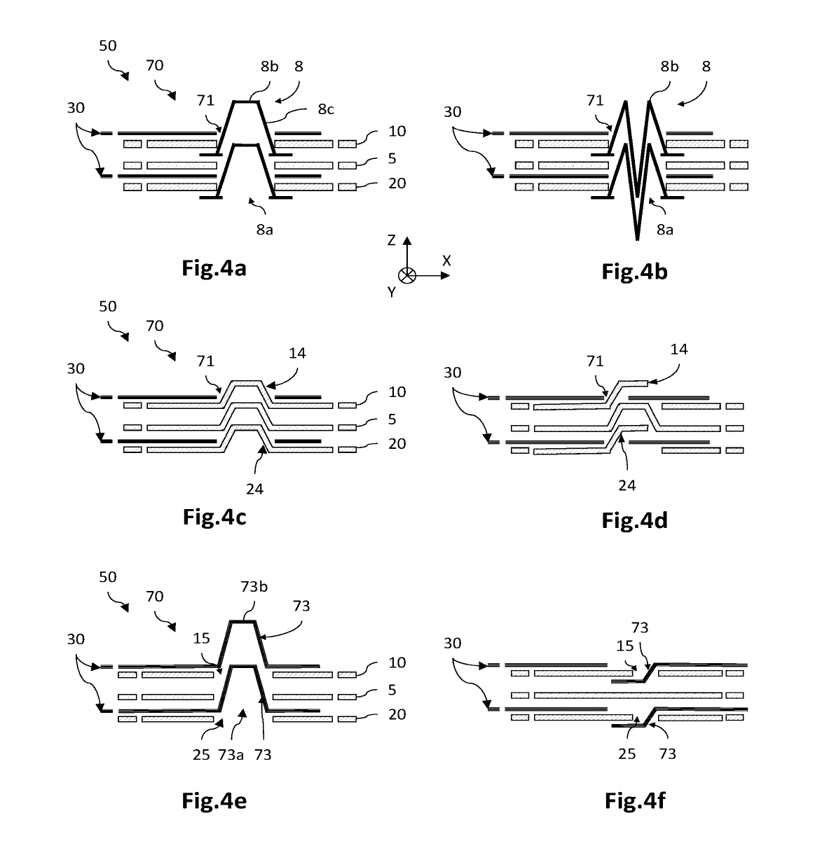

FIGS. 4a to 4f are schematic views in longitudinal cross-section of a blocking area of the electrical connector to the electrochemical cell according to different variant embodiments.

FIGS. 4a and 4b illustrate two variants in which the blocking portion 70 of the electrical connector 30 comprises a blocking through-orifice 71 into which a separate thrust-bearing insert 8, rigidly attached to the electrochemical cell, is inserted.

The bipolar plate 20 facing which the electrical connector 30 is situated here has a through-orifice 26 aligned in the plane (X,Y) with the blocking orifice 71, these orifices receiving the removable insert 8. The latter is therefore rigidly attached to the electrochemical cell and forms an abutment with respect to the end part 50 of the electrical connector, blocking the latter in translation in the plane (X,Y). In this example, the membrane 5 also comprises a through-orifice aligned on the orifices and also receives the removable insert 8.

The removable insert 8 here is a mechanical member forming an embossment making a protrusion with respect to the main plane (X,Y) of the electrochemical cell, which extends along the cell stack Z axis. Here, it takes the form of a hollow truncated cone whose transverse dimension in the plane (X,Y) is substantially equal to the diameter of the blocking orifice. Here, the transverse section, in the plane (X,Y), of the removable insert 8 is rotationally circular but other forms are possible, for example oval, oblong, or even polygonal. The removable insert 8 can provide the abutment against one or more separate end parts. It can extend over the thickness of one or more electrochemical cells.

In the example in FIG. 4a, the removable insert 8 takes the form of a truncated cone and has an open base 8a and also a closed apex 8b connecting the side wall 8c of the trunk of the cone in a substantially plane manner. Several removable inserts 8 are inserted into the stack of cells and aligned along the Z axis. In order to provide a better mechanical strength, the removable inserts 8 are stacked one inside another along the Z axis, in such a manner that the apex 8b of one removable insert is inserted into the base 8a of the adjacent removable insert.

In the example of FIG. 4b, the removable insert 8 has a shape to that of the insert shown in FIG. 4a. It differs from the latter essentially in that the apex 8b has a re-entrant section extending in the direction—Z, this re-entrant section being structured so as to form an opening designed to receive the re-entrant section of the adjacent removable insert. Thus, in order to provide a better mechanical stability, the removable inserts 8 are stacked one inside another along the Z axis in such a manner that the re-entrant section of the apex 8b of a removable insert is introduced into the opening formed by the opening of the apex 8b of the adjacent removable insert.

FIGS. 4c and 4d illustrate two variants in which the blocking portion 70 of the electrical connector 30 comprises a blocking through-orifice 71 into which an abutting embossment 14, 24 formed by the bipolar plate 10, 20 of the electrochemical cell is inserted.

The abutting embossment 14, 24 protrudes with respect to the main plane (X,Y) of the electrochemical cell and extends along the cell stack Z axis. It is inserted into the blocking orifice 71 of the end part 50 of the electrical connector, thus ensuring the blocking in translation of the latter in the plane (X,Y).

The abutting embossment 14, 24 may be implemented in the form of a continuous re-entrant section of the bipolar plate 10, 20 (FIG. 4c) or in the form of a discontinuous re-entrant section (FIG. 4d) corresponding to a localized opening of the bipolar plate 10, 20.

FIGS. 4e and 4f illustrate two variants in which the blocking portion 70 of the electrical connector 30 comprises a blocking element 73 inserted into an abutting through-orifice 15, 25 of a bipolar plate 10, 20 of the electrochemical cell.

The blocking element 73 here is an embossment implemented in the form of a continuous re-entrant section (FIG. 4e) or discontinuous re-entrant section (FIG. 4f) of the blocking portion 70, the re-entrant section extending along the cell stack Z axis and being inserted into an abutting through-orifice 15, 25 formed in a bipolar plate 10, 20 of the electrochemical cell.

In the example of FIG. 4e, the blocking element 73 may take the form of a truncated cone with a substantially circular transverse section in the plane (X,Y), although the shapes previously mentioned may be used. Here, it has a hollow base 73a forming an opening designed to receive the apex 73b of the adjacent blocking embossment 73.

Thus, the insertion of the blocking element 73 into the abutting through-orifice 15, 25 of the electrochemical cell leads to the formation of an abutment opposing the retraction of the end part out of the engaged position.

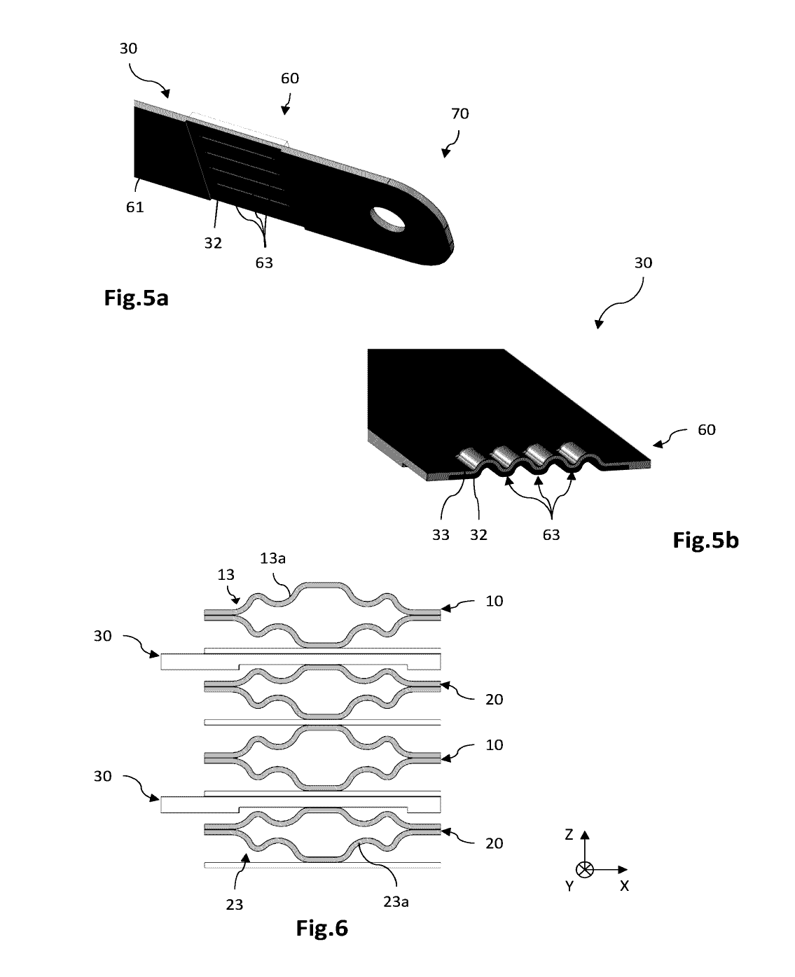

FIGS. 5a and 5b are perspective views of the electrical contact portion of an electrical connector according to other embodiments, in which the contact surface of the conducting core has at least one structural arrangement making a protrusion with respect to the main plane in which it extends, improving the electrical contact between the conducting core and the electrochemical cell.

In the example of FIG. 5a, the conducting core 32 has several protruding structural arrangements 63 in the form of portions 63 with a thickness greater than the average thickness of the conducting core 32 not including the said portions 63. Thus, the electrical contact mainly takes place on the thick portions 63 of the conducting core, which results in an increased mechanical contact pressure between the conducting core and the bipolar plate for the same force applied to the electrochemical cell, thus improving the quality of the electrical contact notably by reducing the electrical resistance at the interface between the conducting core and the bipolar plate.

In the example in FIG. 5b, the electrical contact portion 60 has several protruding structural arrangements 63 in the form of embossments of the conducting core and of the insulating sheath. The conducting core 32 here has an average thickness that is substantially constant on the contact surface 62. Thus, in a similar manner to the variant in FIG. 5a, the electrical contact mainly takes place on the embossments 63 of the conducting core 32, which results in an increased mechanical contact pressure between the conducting core and the bipolar plate for the same force applied to the electrochemical cell, thus improving the quality of the electrical contact notably by reducing the electrical resistance at the interface between the conducting core and the bipolar plate.

It goes without saying that these protruding structural arrangements of the conducting core may be combined with one another and other types of structural arrangements may be envisaged.

FIG. 6 is a schematic longitudinal cross-sectional view of an area of contact of the electrical connector to the electrochemical cell according to another embodiment, in which the bipolar plates 10, 20 comprise contact embossments 13, 23 that are elastically deformable.

The bipolar plates are formed from two metal plates assembled together, and have contact embossments 13, 23 coming into mechanical contact with the end part 50 of the electrical connector. The contact embossments 13, 23 may have structural arrangements 13a, 23a aimed at increasing their capacity to be elastically deformed.

FIG. 6 shows one example of structural arrangements 13a, 23a for the contact embossments 13, 23 in the form of undulations of the metal plates forming the bipolar plates, but other examples of undulations are possible. Thus, when a compression force is applied to the electrochemical cells, the contact embossments 13, 23 are deformed on the structural arrangements 13a, 23a, thus improving the quality of the mechanical, and hence electrical, contact between the bipolar plates and the end part or parts.

In this example, the contact embossments take the form of ribbing running around the periphery of the EMA of the electrochemical cell. As a variant, they may take the form of studs, for example of rotationally cylindrical shape, situated in various positions on the periphery of the EMA.

These contact embossments 13, 23 with structural arrangements 13a, 23a notably allow the local mechanical contact between the electrochemical cells to be maintained, irrespective of the number of end parts 50 engaged in the stack of cells.

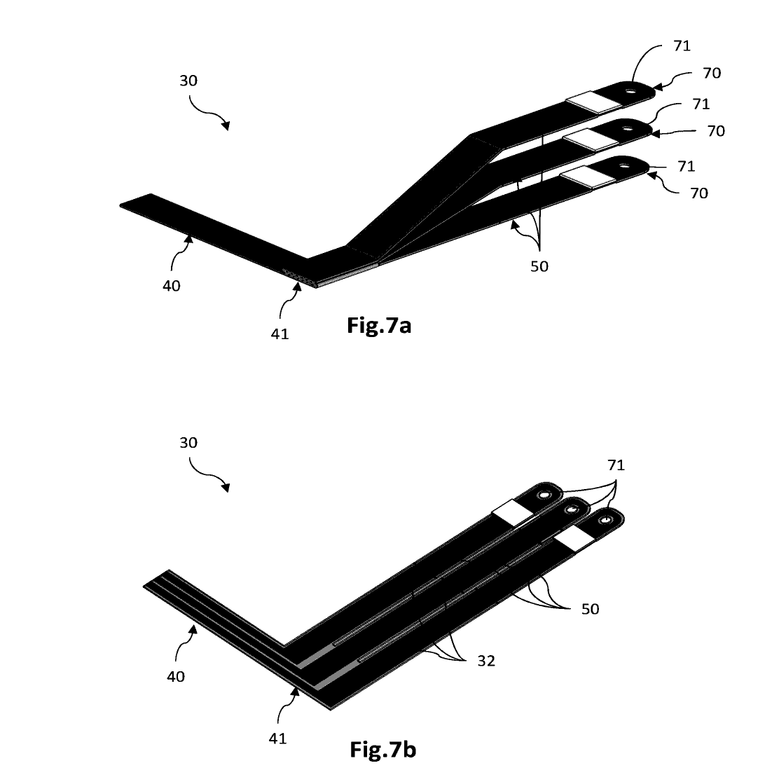

FIGS. 7a and 7b are perspective views of an electrical connector according to another embodiment in which several end parts 50 are mechanically connected to the same external part 40 of the electrical connector.

The external part 40 thus groups the various conducting cores 32 which each extend from an electronic board (not shown) up to the respective end parts 50.

FIG. 7a illustrates the electrical connector comprising end parts 50 arranged so as to be engaged into the stack of electrochemical cells. The various end parts 50 are superposed one on top of the other in such a manner that the blocking through-orifices 71 are aligned along the Z axis of the stack of cells. They meet at a common 10 junction section 41 in which the conducting cores 32 are superposed and isolated from one another by the insulating sheath 33. The conducting cores 32 subsequently extend into the external part 40 while here being disposed side by side between the two main faces of the external part.

FIG. 7b illustrates the electrical connector prior to the step for positioning the end parts 50, this step here being carried out by bending at the junction section 41. An insulating sheath 33 covering one face of the conducting cores 32 here is transparent in order to make visible the channelling of the conducting cores 32 within the external part 40, within the junction section 41 and within the end parts 50.

Other configurations of the end parts relative to the external part are possible, for example applying more bending steps at the junction section.

Some particular embodiments have just been described. Several variants and modifications will be apparent to those skilled in the art.

Thus, an end part has been described that comprises a single conducting core, even though it is able to comprise several conducting cores, mutually superposed and/or laterally shifted. These are then isolated from one another by the insulating sheath. Thus, such an end part may be in electrical contact with the two bipolar plates of the same electrochemical cell when the electrical contact portion comprises two contact surfaces opposite to each other. Such an end part may also provide at least two electrical contacts with the same bipolar plate when the electrical contact portion comprises several contact surfaces situated on the same face of the end part but isolated from one another. It is then possible to apply an electrical potential and to measure the electrical response of the cell at the same time.

Furthermore, the electrical contact has been described between the conducting core of the connector and a bipolar plate of an electrochemical cell on a contact embossment. Alternatively, the electrical contact may be made by means of a lateral reinforcement member equipped with a conducting track in electrical contact with a bipolar plate or an electrode of an electrochemical cell.

The measurement of an electrical potential on an electrochemical cell has principally been described, but the electrical connector also allows an electrical potential to be applied, notably when it is desired to analyze the electrochemical behaviour of the cell by a method of the spectroscopy, impedance or voltamperometry type.

1.-15. (canceled)

16. An electrochemical reactor, comprising:
a stack of electrochemical cells each comprising two electrodes separated from each other by an electrolyte and in electrical contact with bipolar plates, and comprising at least one abutment element or an abutting through-orifice of an electrochemical cell; and
at least one electrical connector, providing an electrical connection with the electrochemical cell of the stack of electrochemical cells, the electrical connector comprising an end part inserted into the stack of electrochemical cells and occupying a position referred to as engaged, the end part comprising:
an electrical contact portion, being in electrical contact with a bipolar plate of the electrochemical cell when the end part occupies the engaged position; and
a blocking portion, cooperating with the electrochemical cell in order to ensure the maintenance of the end part in the engaged position, comprising:
either a blocking through-orifice receiving by insertion the abutment element of the electrochemical cell,
or a blocking element introduced by insertion into the abutting through-orifice of the electrochemical cell,
the insertion, leading to the formation of an abutment opposing the retraction of the end part out of the engaged position,
wherein the end part is composed of an electrical cable comprising a conducting core in the form of a strip having two faces opposite to each other coated with an insulating sheath, and has an average thickness, between two main faces of the end part substantially parallel and opposite to each other, less than the width and length dimensions of the main faces.

17. The electrochemical reactor according to claim 16, wherein the insulating sheath extends over the electrical contact and blocking portions on the two main faces of the end part.

18. The electrochemical reactor according to claim 16, wherein the end part has an average thickness in a range between 20 μm and 500 μm.

19. The electrochemical reactor according to claim 16, wherein the blocking through-orifice or the blocking element runs in a thickness direction of the end part, and is electrically isolated from the conducting core by the insulating sheath.

20. The electrochemical reactor according to claim 16, wherein the electrical contact portion and the blocking portion are distinct from each other and mutually spaced out along a longitudinal axis of the electrical connector.

21. The electrochemical reactor according to claim 16, wherein the electrical contact portion comprises a main face, oriented towards the bipolar plate, having a region not having any insulating sheath freeing up a contact surface of the conducting core, the contact surface being in electrical contact with the bipolar plate.

22. The electrochemical reactor according to claim 21, wherein the face of the conducting core opposite to the main face is coated with the insulating sheath.

23. The electrochemical reactor according to claim 21, wherein the contact surface of the conducting core has at least one structural arrangement making a protrusion with respect to a main plane in which the contact surface of the conducting core substantially extends, the protruding structural arrangement being elastically deformable.

24. The electrochemical reactor according to claim 16, wherein the blocking portion comprises a blocking through-orifice configured to receive an abutment element chosen from amongst a centring pin passing through the stack of electrochemical cells, a removable insert, and an embossment formed by the bipolar plate.

25. The electrochemical reactor according to claim 24, wherein the blocking portion comprises an open slot extending from the blocking through-orifice up to a lateral edge of the blocking portion, the open slot having a width substantially less than a diameter of the blocking through-orifice.

26. The electrochemical reactor according to claim 24, wherein the blocking through-orifice of the blocking portion extends up to a lateral edge of the blocking portion at an opening area of the blocking orifice, the latter being positioned between the blocking through-orifice and the electrical contact portion.

27. The electrochemical reactor according to claim 16, wherein the blocking portion comprises a blocking element in the form of an embossment configured to be inserted into an abutting through-orifice of the electrochemical cell.

28. The electrochemical reactor according to claim 16, further comprising a plurality of separate end parts providing an electrical connection with various bipolar plates, the end parts being mechanically connected to the same part, referred to as external part, of the electrical connector.

29. The electrochemical reactor according to claim 16, wherein the bipolar plates comprise contact embossments, elastically deformable, the end part comprising a contact portion in contact with the contact embossments.

30. A method for producing an electrochemical reactor according to claim 16, comprising:
a step for formation of the stack of electrochemical cells, during which, between two stacks of bipolar plates, the electrical connector is stacked in such a manner that the end part occupies the engaged position, resulting in:
an electrical contact between the electrical contact portion and a bipolar plate,
and
the formation of an abutment opposing the retraction of the end part out of the engaged position by the insertion of the abutment element into the blocking through-orifice or by the insertion of the blocking element into the abutting through-orifice.
